(19) United States
(12) Patent Application Publication
(10) Pub. No.: US 2022/0297917 A1
(43) Pub. Date: Sep. 22, 2022

(54) HEAT INSULATING CONTAINER AND METHOD FOR PRODUCING THE SAME

(71) Applicants: Thermos L.L.C., Schaumburg, IL (US); THERMOS K.K., Tsubame-shi (JP)

(72) Inventor: Yasuhiro KOWA, Tsubame-shi (JP)

(21) Appl. No.: 17/693,958

(22) Filed: Mar. 14, 2022

(30) Foreign Application Priority Data
Mar. 18, 2021 (JP) 2021-044550

(51) Int. Cl. B65D 81/38; C23C 16/26; C23C 16/50; C23C 16/56; C23C 16/40; C23C 16/02; C23C 16/32

(52) U.S. Cl. CPC B65D 81/3823; C23C 16/26; C23C 16/50; C23C 16/56; C23C 16/402; C23C 16/0272; C23C 16/325

(57) ABSTRACT

A heat insulating container is described. An inner surface of an inner container of the heat insulating container is coated to have excellent wear resistance and corrosion resistance to prevent the adhesion of stains and odors. The heat insulating container includes an outer container and the inner container which are made of metal and have one end open. The inner container is housed inside the outer container. The open ends are joined to each other. A vacuum insulating layer is formed between the outer container and the inner container. An insulating layer and a diamond-like carbon (DLC) layer are sequentially laminated on the inner surface of the inner container.

The present application claims priority to Japanese Patent Application No. 2021-044550 filed on Mar. 18, 2021.

### FIELD OF INVENTION

The present invention relates to a heat insulating container and a method for producing the same.

### BACKGROUND

Conventionally, a heat insulating container includes an outer container and an inner container which are made of metal and have one end open, and the inner container is housed inside the outer container, the open ends are joined to each other, and a vacuum insulating layer is formed between the outer container and the inner container. A heat insulating container having such a vacuum insulating structure can have excellent heat and cold insulation functions.

In the conventional heat insulating container, the inner surface of the inner container is coated with a fluororesin. By coating with fluororesin, a base material metal of the inner container is covered, so that it is possible to prevent scratches and rust on the base material. In addition, it is also possible to make it easier to keep the inside of the inner container hygienic and to improve the detergency of the inside of the inner container.

However, the scratch hardness of a general fluororesin coating is about HB to 6 H in terms of pencil hardness. For this reason, in the heat insulating container coated with the fluororesin described above, the fluororesin coating gradually wears and scratches as it is used continuously. As a result, a part of the fluororesin coating is peeled off, that is, a so-called pinhole is generated, and the fluororesin coating is easily peeled off from the pinhole as a starting point.

Since the rust preventive function is lost at the portion at which the fluororesin coating is peeled off, corrosion such as rust is likely to occur on the metal at the surface of the base material. On the other hand, if the film thickness of the fluororesin coating is made too thick in order to prevent the occurrence of pinholes, the adhesion of the fluororesin coating is lowered, and the fluororesin coating is easily peeled off. Therefore, it is necessary to set the fluororesin coating to an appropriate thickness.

In addition, odors and the like are easily adsorbed on the fluororesin coating, and there is also the odor of the fluororesin itself. Therefore, the odor may remain inside the inner container as it is used continuously. Further, the water repellency of the fluororesin coating is gradually lost, so that dirt and the like tend to remain inside the inner container. Therefore, it becomes difficult to keep the inside of the inner container hygienic.

Stainless steel is often used as the base material of the conventional heat insulating container. Among them, grades such as SUS304 are often used. This is because stainless steel such as SUS304 has a passivation film on the surface and thus has corrosion resistance.

However, since the passivation film on the surface of stainless steel is not completely uniform, there are thin parts and missing parts, and rust may occur from such weak parts of the passivation film.

For this reason, in general, the passivation film is made uniform by surface treatment such as acid cleaning or polishing, or the surface of the stainless steel itself is covered by plating treatment or painting treatment. This makes it possible to suppress the generation of rust while keeping the inner surface of the heat insulating container hygienic.

However, it is difficult to completely prevent the generation of fine pinholes on the surface of the stainless steel by the surface treatment and coating treatment. If pinholes are generated in the coating treatment, it leads to peeling of the coated portion. Furthermore, if pinholes occur in the passivation film, point corrosion will occur in the stainless steel, the corrosion will reach the vacuum insulation layer, the vacuum performance deteriorates, and the heat and cold insulation functions are lost.

The prior art includes Japanese Unexamined Patent Application, First Publication No. 2020-199013.

### SUMMARY OF INVENTION

A heat insulating container having a diamond-like carbon (DLC) coating is described. The DLC coating has better wear resistance and corrosion resistance than those of the conventional fluororesin coatings described above and prevents the adhesion of dirt and odor. The DLC coating may be applied to an inner surface of an inner container of the heat insulating container.

The heat insulating container, having the inner surface of the inner container coated with the DLC coating, provides excellent wear resistance and corrosion resistance to prevent the adhesion of stains and odors. A method for producing the heat insulating container is also described.

In one aspect, a heat insulating container includes an outer container and an inner container which are made of metal and have one end open, and the inner container is housed inside the outer container, the open ends are joined to each other, and a vacuum insulating layer is formed between the outer container and the inner container, wherein an insulating layer and a diamond-like carbon (DLC) layer are sequentially laminated on an inner surface of the inner container.

In another aspect, a thickness of the insulating layer is equal to or greater than a thickness of the DLC layer.

In another aspect, a total thickness of each layer laminated on the inner surface of the inner container is 4 to 250 nm.

In another aspect, the thickness of the insulating layer is A and the thickness of the DLC layer is B, the relationship of A:B=(1 to 9):1 is satisfied.

In another aspect, a surface of the DLC layer is modified with fluorine.

In another aspect, a fluorine-containing DLC layer is laminated on the DLC layer.

In another aspect, the thickness of the insulating layer is A, the thickness of the DLC layer is B, and the thickness of the fluorine-containing DLC layer is C, the relationship of A:B:C=(5 to 8):(1 to 2.5):(1 to 2.5) is satisfied.

In another aspect, the insulating layer is made of a silicon oxide film containing silicon and oxygen, and the DLC layer is made of an amorphous hard carbon film containing carbon and hydrogen.

In another aspect, an intermediate layer, the insulating layer, and the DLC layer are sequentially laminated on the inner surface of the inner container.

In another aspect, the insulating layer, an intermediate layer, and the DLC layer are sequentially laminated on the inner surface of the inner container.

In another aspect, when the thickness of the intermediate layer is D, the thickness of the insulating layer is A, and the thickness of the DLC layer 12 is B, the relationship of D:A:B=(1 to 8):(1 to 8):1 is satisfied.

In another aspect, the surface of the DLC layer is modified with fluorine.

In another aspect, a fluorine-containing DLC layer is laminated on the DLC layer.

In another aspect, the thickness of the intermediate layer is D, the thickness of the insulating layer is A, the thickness of the DLC layer is B, and the thickness of the fluorine-containing DLC layer is C, the relationship of D:A:B:C=(1 to 8):(1 to 8):(1 to 2.5):(1 to 2.5) is satisfied.

In another aspect, the intermediate layer is made of an amorphous silicon carbide film containing at least one element of nitrogen, hydrogen, and oxygen together with carbon and silicon.

In another aspect, the inside of the inner container is colored.

In another aspect, a method for producing a heat insulating container is described. The heat insulating container includes an outer container and an inner container which are made of metal and have one end open, and the inner container is housed inside the outer container, the open ends are joined to each other, and a vacuum insulating layer is formed between the outer container and the inner container. The method includes a step of sequentially laminating an insulating layer and a diamond-like carbon (DLC) layer on the inner surface of the inner container by using a plasma chemical vapor deposition (plasma CVD).

In another aspect the thickness of the insulating layer is equal to or greater than the thickness of the DLC layer.

In another aspect, the insulating layer and the DLC layer are sequentially laminated by putting the heat insulating container in a film-forming chamber, decompressing an inside of the film-forming chamber, turning raw material gases of the insulating layer and the DLC layer sequentially introduced inside the inner container into plasma while applying a voltage between the heat insulating container on a cathode side and an auxiliary electrode on an anode side.

In another aspect, method further includes a step of modifying a surface of the DLC layer with fluorine.

In another aspect the method further includes a step of laminating a fluorine-containing DLC layer on the DLC layer.

In another aspect an organosilicon compound gas and a gas containing oxygen are used as a raw material gas of the insulating layer, and a hydrocarbon-based gas is used as a raw material gas of the DLC layer.

In another aspect the method includes a step of sequentially laminating an intermediate layer, the insulating layer, and the DLC layer on the inner surface of the inner container by using a plasma chemical vapor deposition (plasma CVD) method.

In another aspect the method includes a step of sequentially laminating the insulating layer, an intermediate layer, and the DLC layer on the inner surface of the inner container by using a plasma chemical vapor deposition (plasma CVD) method.

In another aspect an organosilicon compound gas is used as a raw material gas of the intermediate layer.

As described above, a heat insulating container is provided in which the inner surface of the inner container is coated to have excellent wear resistance and corrosion resistance to prevent the adhesion of stains and odors. A method for producing the heat insulating container is also described.

### BRIEF DESCRIPTION OF DRAWINGS

FIG. 1 is a cross-sectional view showing a heat insulating container of an embodiment according to the present invention.

FIG. 2 is an enlarged view showing a part of the inside of the inner container of the heat insulating container shown in FIG. 1, FIG. 2A is a cross-sectional view showing Example 1-1, and FIG. 2B is a cross-sectional view showing Example 1-2.

FIG. 3 is an enlarged view showing a part of the inside of the inner container of the heat insulating container shown in FIG. 1, FIG. 3A is a cross-sectional view showing Example 2-1 and FIG. 3B is a cross-sectional view showing Example 2-2.

FIG. 4 is an enlarged view showing a part of the inside of the inner container of the heat insulating container shown in FIG. 1, FIG. 4A is a cross-sectional view showing Example 3-1 and FIG. 4B is a cross-sectional view showing Example 3-2.

FIG. 5 is a flowchart showing production processes of the heat insulating container shown in FIG. 1.

### DETAILED DESCRIPTION

Hereinafter, aspects of the present invention will be described in detail with reference to the figures. In addition, in the figures used in the following explanation, in order to make the features easy to understand, the featured parts may be enlarged for convenience, and the dimensional ratios of each component may not be the same as the actual ones. Further, the materials, dimensions, and the like in the following description are examples, but the present invention is not necessarily limited to them, and the present invention can be appropriately modified without changing the gist thereof.

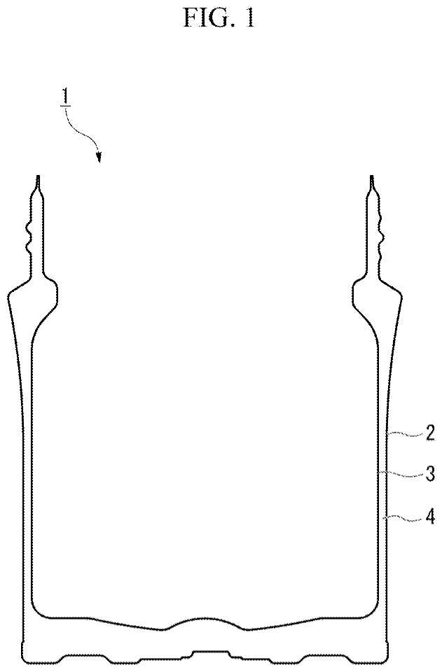

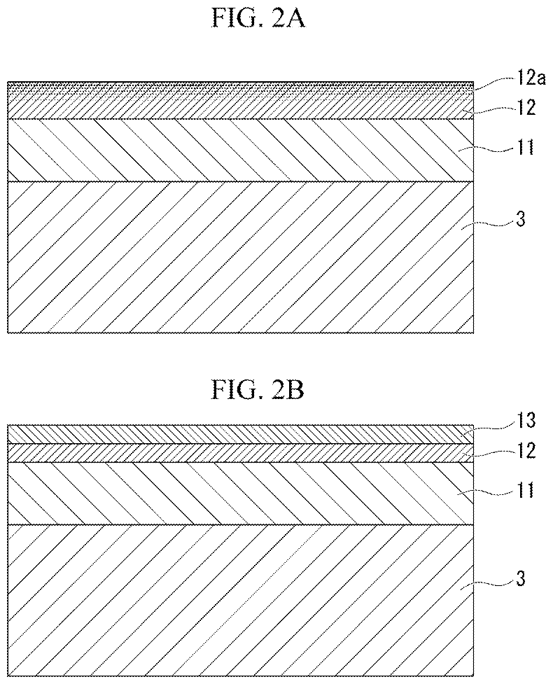

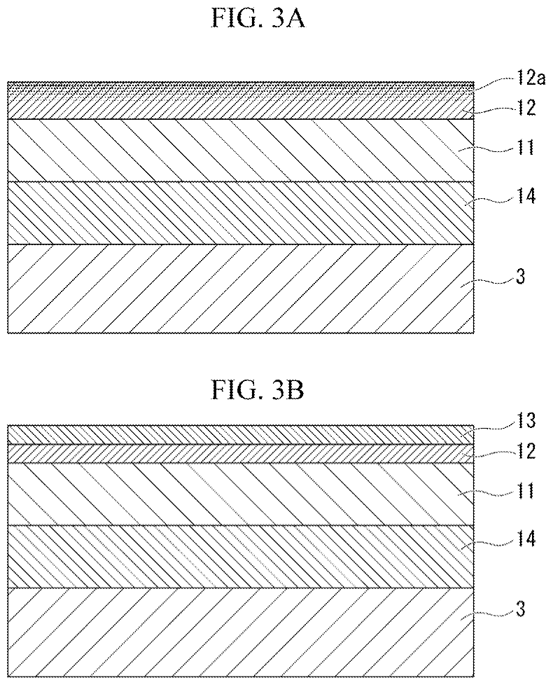

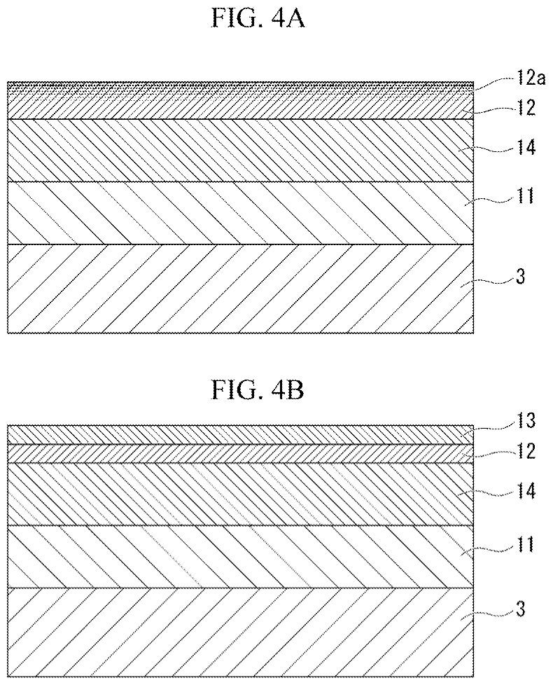

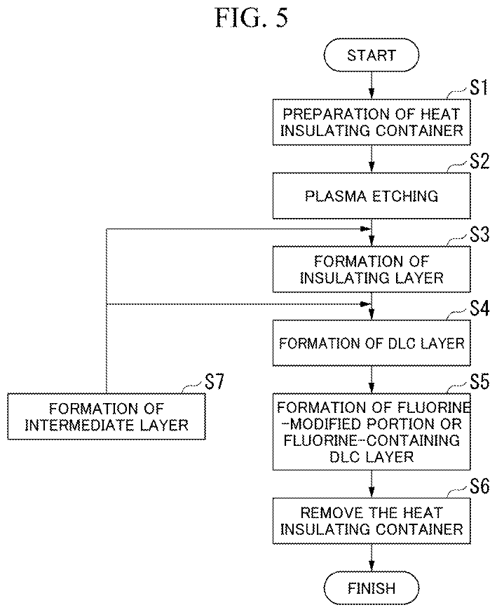

As an embodiment of the present invention, for example, the heat insulating container 1 shown in FIGS. 1 to 4 will be described. FIG. 1 is a cross-sectional view showing a heat insulating container 1. FIG. 2 is an enlarged view showing a part of the inside of an inner container 3, FIG. 2A is a cross-sectional view showing Example 1-1, and FIG. 2B is a cross-sectional view showing Example 1-2. FIG. 3 is an enlarged view showing a part of the inside of the inner container 3, FIG. 3A is a cross-sectional view showing Example 2-1 and FIG. 3B is a cross-sectional view showing Example 2-2. FIG. 4 is an enlarged view showing a part of the inside of the inner container 3, FIG. 4A is a cross-sectional view showing Example 3-1 and FIG. 4B is a cross-sectional view showing Example 3-2. FIG. 5 is a flowchart showing production processes of the heat insulating container shown in FIG. 1.

As shown in FIG. 1, the heat insulating container 1 of the present embodiment includes an outer container 2 and the inner container 3 which are made of metal, such as stainless steel. In the heat insulating container 1, the inner container 3 having an open end is housed inside the outer container 2 having an open end, and the periphery of each open end is joined to each other. The heat insulating container 1 has a vacuum heat insulating structure in which a vacuum insulating layer 4 is provided between the outer container 2 and the inner container 3.

The vacuum heat insulating layer 4 can be formed, for example, by closing a degassing hole provided in the center of the bottom surface of the outer container 2 in a chamber decompressed (evacuated) to a high vacuum.

Since the heat insulating container 1 has such a vacuum insulating structure, the heat insulating container 1 has functions such as heat retention and cold retention.

Further, in the heat insulating container 1 of the present embodiment, it is possible to open and close the upper opening of the heat insulating container 1 by a lid (not shown) which is detachable from to the heat insulating container 1 by screwing.

The heat insulating container 1 of the present embodiment has a substantially cylindrical shape as a whole, but the shape of the heat insulating container 1 is not particularly limited thereto. The shape of the heat insulating container 1 can be changed as appropriate according to the size and design. Further, the outer peripheral surface of the outer container 2 may be painted or printed.

In the heat insulating container 1 of the present embodiment, an insulating layer 11 and a diamond-like carbon (DLC) layer 12 are sequentially laminated on the inner surface of the inner container 3 as in Example 1-1 shown in FIG. 2A. Further, the DLC layer 12 may be provided with a fluorine-modified portion 12a of which the surface is modified with fluorine.

In the heat insulating container 1 of the present embodiment, as in Example 1-2 shown in FIG. 2B, the insulating layer 11, the diamond-like carbon (DLC) layer 12, and a fluorine-containing DLC layer 13 may be sequentially laminated on the inner surface of the inner container 3. The layer obtained by modifying the surface of the DLC layer 12 with fluorine is the fluorine-modified portion 12a. The layer newly provided on the DLC layer 12 is the fluorine-containing DLC layer 13.

The insulating layer 11 is made of a silicon oxide film containing silicon (Si) and oxygen (O). The insulating layer 11 is provided between the inner surface of the inner container 3 and the DLC layer 12 in order to protect the surface of the inner container 3, suppress point corrosion of metal, and improve the adhesion of the DLC layer 12.

The insulating layer 11 is preferably made of a silicon oxide film containing silicon dioxide (SiO₂) as a main component since silicon dioxide (SiO₂) has a large electric resistance and excellent durability. Therefore, deterioration due to point corrosion can be suppressed by coating the surface of the metal with silicon dioxide (SiO₂).

The thickness of the insulating layer 11 is equal to or greater than the thickness of the DLC layer 12. This is because when the thickness of the insulating layer 11 is equal to or greater than the thickness of the DLC layer 12, the adhesion between the inner surface of the inner container 3 and the DLC layer 12 increases, and the DLC layer 12 is hardly peeled off.

The DLC layer 12 is made of an amorphous hard carbon film containing carbon (C) and hydrogen (H), such as hydrogenated tetrahedral amorphous carbon (ta-C:H) and hydrogenated amorphous carbon (a-C:H). The hydrogen content of the DLC layer 12 is preferably 10 to 40 atomic %, and particularly preferably 20 to 30 atomic %. Further, the DLC layer 12 may be made of, for example, an amorphous hard carbon film containing no hydrogen (H) such as tetrahedral amorphous carbon (ta-C) or amorphous carbon (a-C). The DLC layer 12 preferably has a Knoop hardness (HK) of 1500 to 3000.

The DLC layer 12 has excellent properties such as high hardness, low friction, chemically inertness, high releasability, and non-adsorption property. Thereby, it is possible to improve wear resistance, corrosion resistance, detergency, and the like inside the inner container 3. In addition, it is also possible to prevent the adhesion of dirt and odor.

The total thickness of the insulating layer 11 and the DLC layer 12 or the total thickness of the insulating layer 11, the DLC layer 12, and the fluorine-containing DLC layer 13 is preferably 4 to 250 nm. When the total thickness is equal to or greater than 4 nm, it is easy to form a uniform film inside the inner container 3. On the other hand, when the total thickness is equal to or less than 250 nm, the inner container 3 can withstand the deformation of the inner container 3 and deformation pressure due to an external force, and breakage or peeling is hardly to occur. Further, if the total thickness is increased, the raw material cost for film formation increases, which is uneconomical.

In the heat insulating container 1 of the present embodiment, it is possible to evenly color the inside of the inner container 3 over the entire surface by making the total thickness of the insulating layer 11 and the DLC layer 12 or the total thickness of the insulating layer 11, the DLC layer 12, and the fluorine-containing DLC layer 13 uniform. It is also possible to change the color by controlling the total thickness of these layers.

Further, in the heat insulating container 1 of the present embodiment, when the thickness of the insulating layer 11 is A and the thickness of the DLC layer 12 is B, it is preferable that the relationship of the following formula (1) be satisfied.

A:B=(1 to 9):1 (1)

By satisfying the relationship of the formula (1) above, the adhesion between the inner surface of the inner container 3 and the DLC layer 12 can be stably maintained by the insulating layer 11.

The fluorine-modified portion 12a is obtained by modifying the surface of the DLC layer 12 with fluorine, and the fluorine concentration decreases from the surface of the DLC layer 12 toward the depth direction. On the other hand, the fluorine-containing DLC layer 13 is an amorphous hard carbon film containing fluorine (F), and is provided by being laminated on the DLC layer 12.

In the heat insulating container 1 of the present embodiment, it is preferable that the contact angle of water on the surface of the DLC layer 12 containing the fluorine-modified portion 12a or the surface of the fluorine-containing DLC layer 13 be 80° or more, and the Knoop hardness (HK) be 1000 or more. Thereby, it is possible to obtain the fluorine-containing DLC layer 13 having high-hardness and excellent water repellency.

Further, in the heat insulating container 1 of the present embodiment, when the thickness of the insulating layer 11 is A, the thickness of the DLC layer 12 is B, and the thickness of the fluorine-containing DLC layer 13 is C, it is preferable that the relationship of the following formula (2) be satisfied.

A:B:C=(5 to 8):(1 to 2.5):(1 to 2.5) (2)

By satisfying the relationship of the formula (2) above, it is possible to provide the fluorine-containing DLC on the DLC layer 12 while stably maintaining the adhesion between the inner surface of the inner container 3 and the DLC layer 12.

Further, in the heat insulating container 1 of the present embodiment, as in Example 2-1 shown in FIG. 3A, an intermediate layer 14, the insulating layer 11, and the DLC layer 12 may be sequentially laminated on the inner surface of the inner container 3. Further, the DLC layer 12 may be provided with the fluorine-modified portion 12a of which the surface is modified with fluorine.

In the heat insulating container 1 of the present embodiment, as in Example 2-2 shown in FIG. 3B, the intermediate layer 14, the insulating layer 11, the DLC layer 12, and the fluorine-containing DLC layer 13 may be sequentially laminated on the inner surface of the inner container 3.

In the heat insulating container 1 of the present embodiment, as in Example 2-1 shown in FIG. 4A, the insulating layer 11, the intermediate layer 14, and the DLC layer 12 may be sequentially laminated on the inner surface of the inner container 3. Further, the DLC layer 12 may be provided with a fluorine-modified portion 12a of which the surface is modified with fluorine.

In the heat insulating container 1 of the present embodiment, as in Example 2-2 shown in FIG. 4B, the insulating layer 11, the intermediate layer 14, the DLC layer 12, and the fluorine-containing DLC layer 13 may be sequentially laminated on the inner surface of the inner container 3.

The intermediate layer 14 is made of an amorphous silicon carbide film containing at least one element of nitrogen (N), hydrogen (H), and oxygen (O) together with carbon (C) and silicon (Si). The intermediate layer 14 is provided between the inner surface of the inner container 3 and the insulating layer 11 or between the insulating layer 11 and the DLC layer 12 in order to improve the adhesion.

The total thickness of the intermediate layer 14, the insulating layer 11, and the DLC layer 12 or the total thickness of the intermediate layer 14, the insulating layer 11, the DLC layer 12, and the fluorine-containing DLC layer 13 is preferably 4 to 250 nm. When the total thickness is equal to or greater than 4 nm, it is easy to form a uniform film inside the inner container 3. On the other hand, when the total thickness is equal to or less than 250 nm, the inner container 3 can withstand the deformation of the inner container 3 and deformation pressure due to an external force, and breakage or peeling is hardly to occur. Further, if the total thickness is increased, the raw material cost for film formation increases, which is uneconomical.

In the heat insulating container 1 of the present embodiment, it is possible to evenly color the inside of the inner container 3 over the entire surface by making the total thickness of the insulating layer 11 and the DLC layer 12 or the total thickness of the insulating layer 11, the DLC layer 12 and the fluorine-containing DLC layer 13 uniform. It is also possible to change the color by controlling the total thickness of these layers.

Further, in the heat insulating container 1 of the present embodiment, when the thickness of the intermediate layer 14 is D, the thickness of the insulating layer 11 is A, and the thickness of the DLC layer 12 is B, it is preferable that the relationship of the following formula (3) be satisfied.

D:A:B=(1 to 8):(1 to 8):1 (3)

By satisfying the relationship of the formula (3) above, the adhesiveness between the inner surface of the inner container 3 and the insulating layer 11 or between the insulating layer 11 and the DLC layer 12 can be stably maintained by the intermediate layer 14.

Further, in the heat insulating container 1 of the present embodiment, when the thickness of the intermediate layer 14 is D, the thickness of the insulating layer 11 is A, the thickness of the DLC layer 12 is B, and the thickness of the fluorine-containing DLC layer 13 is C, it is preferable that the relationship of the following formula (4) be satisfied.

D:A:B:C=(1 to 8):(1 to 8):(1 to 2.5):(1 to 2.5) (4)

By satisfying the relationship of the formula (4) above, it is possible to provide the fluorine-containing DLC layer 13 having excellent properties on the DLC layer 12 while the adhesion between the inner surface of the inner container 3 and the insulating layer 11 or between the insulating layer 11 and the DLC layer 12 can be stably maintained by the intermediate layer 14.

As described above, the heat insulating container 1 of the present embodiment has a coating (hereinafter referred to as “DLC coating”) on the inner surface of the inner container 3 which is superior in durability and abrasion resistance to those of the conventional fluororesin coating and prevents the adhesion of stains and odors.

Further, in the heat insulating container 1 of the present embodiment, the insulating layer 11 having a large electric resistance and excellent durability is provided on the inner surface of the inner container 3 or on the intermediate layer 14. Therefore, the occurrence of point corrosion is suppressed. Further, since the coating treatment is performed on the DLC layer 12 or the like, the surface can be kept stable.

Next, the method for producing the heat insulating container 1 will be described with reference to FIG. 5. Note that FIG. 5 is a flowchart showing the production process of the heat insulating container 1.

In the method for producing the heat insulating container 1 of the present embodiment, the insulating layer 11 and the DLC layer 12 are sequentially laminated on the inner surface of the inner container 3 by using a plasma chemical vapor deposition (plasma CVD) method. Then, the fluorine-modified portion 12a of which the surface of the DLC layer 12 is modified with fluorine is formed. Alternatively, the fluorine-containing DLC layer 13 is formed on the DLC layer 12.

Specifically, first, in step S1 shown in FIG. 5, the heat insulating container 1 before applying the DLC coating (before film formation) is prepared.

Next, in step S2 shown in FIG. 5, the heat insulating container 1 is placed in a holder in a film-forming chamber (chamber) of a plasma CVD film-forming apparatus, and then the inside of the film-forming chamber is depressurized by vacuuming. A voltage is applied between the heat insulating container 1 on the cathode side and an auxiliary electrode on the anode side. Since the heat insulating container 1 is made of a conductive material (metal), it functions as a cathode.

At this time, the frequency of the high-frequency power supply is preferably 50 kHz or more and 13.56 MHz or less, and more preferably 500 kHz or more and 800 kHz or less. The pressure in the film-forming chamber is preferably 0.5 Pa or more and 100 Pa or less.

In this state, argon (Ar) gas is introduced into the inside of the inner container 3 through an introduction tube to generate plasma, so that the inner surface of the inner container 3 is plasma-etched. As a result, the surface of the base material of the inner container 3 is treated (cleaned). Further, instead of Ar gas, another inert gas (for example, Xe, He, N₂, etc.) can be used.

The surface of the base material of the inner container 3 can be heated by the plasma etching. At this time, the surface temperature of the base material is preferably 80 to 250° C., and more preferably 120 to 200° C. When the surface temperature of the base material is 80° C. or higher, the temperature at which the insulating layer 11 and the DLC layer 12 are formed on the inner surface of the inner container 3 described later can be secured, and it is difficult for the DLC layer 12 to be peeled off. On the other hand, when the surface temperature of the base material is 250° C. or lower, the time required for plasma etching can be shortened, which is preferable in consideration of the production cost.

Next, in step S3 shown in FIG. 5, a raw material gas of the insulating layer 11 is introduced into the inner container 3 through an introduction pipe and turned into plasma to form the insulating layer 11 on the inner surface of the inner container 3.

Specifically, examples of the raw material gas of the insulating layer 11 include a gas (oxidizing gas) containing oxygen (O₂), nitrous oxide (N₂O), ozone (O₃) along with an organosilicon compound gas such as tetramethylsilane (Si(CH₃)₄), trimethoxysilane (SiH(OCH₃)₃) tetraethoxysilane (Si(OC₂H₅)₄), hexamethyldisilazane (C₆H₁₉NSi₂), hexamethyldisiloxane (C₆H₁₈OSi₂), and trisdimethylaminosilane (SiH[N(CH₃)₂]₃).

The organosilicon compound gas and the oxidizing gas, which are the components of the raw material gas of the insulating layer 11, are introduced into the inner container 3. At this time, the raw material gas of the insulating layer 11 is put into a plasma state, and the insulating layer 11 is formed while depositing the generated radicals and ions on the inner surface (base material surface) of the inner container 3.

Next, in step S4 shown in FIG. 5, a raw material gas of the DLC layer 12 is introduced into the inner container 3 through the introduction pipe and turned into plasma, whereby the DLC is formed on the inner surface of the inner container 3 via the insulating layer 11.

Specifically, examples of the raw material gas of the DLC layer 12 include hydrocarbon-based gas such as methane (CH₄), ethane (C₂H₆), ethylene (C₂H₄), acetylene (C₂H₂), and toluene (C₆H₅CH₃). The raw material gas of the DLC layer 12 is introduced into the inner container 3. At this time, the raw material gas of the DLC layer 12 is put into a plasma state, and the DLC layer 12 is formed while depositing the generated radicals and ions on the insulating layer 11.

As described above, it is possible to improve the adhesion between the inner surface of the inner container 3 and the DLC layer 12 through the insulating layer 11 by setting the thickness of the insulating layer 11 to be equal to or greater than the thickness of the DLC layer 12. Further, it is preferable to satisfy the relationship of the formula (1) above. As a result, the adhesion between the inner surface of the inner container 3 and the DLC layer 12 can be stably maintained by the insulating layer 11.

Further, it is preferable to heat the inner surface of the inner container 3 by the heating step including the plasma etching described above before forming the insulating layer 11. In this case, since the insulating layer 11 is formed on the surface of the thermally expanded inner container 3, the insulating layer 11 and the DLC layer 12 which have reached room temperature after the film formation are subjected to compressive stress due to the shrinkage of the inner container 3 due to cooling. Thereby, when a hot beverage or the like is put in the heat insulating container 1 at the time of use, it is possible to avoid applying tensile stress to the insulating layer 11 and the DLC layer 12 due to the thermal expansion of the inner container 3. As a result, it is possible to prevent cracks from occurring in the insulating layer 11 and the DLC layer 12, and to improve the adhesion of the DLC layer 12.

Next, in step S5 shown in FIG. 5, the fluorine-modified portion 12a is formed by modifying the surface of the DLC layer 12 with fluorine. Alternatively, the fluorine-containing DLC layer 13 is formed on the DLC layer 12.

Specifically, the surface of the DLC12 layer is modified by introducing a fluorine-based gas such as tetrafluoromethane (CF₄), hexafluoroethane (C₂F₆), octafluoropropane (C₃F₈), octafluorocyclobutane (c-C₄F₈), trifluoromethane (CHF₃), sulfur hexafluoride (SF₆) and trifluoroamine (NF₃) and converting it into plasma. As a result, the fluorine-modified portion 12a can be formed in the surface of the DLC layer 12.

When forming the fluorine-modified portion 12a, the fluorine concentration in the thickness direction of the fluorine-modified portion 12a can be adjusted by adjusting the amount and the reaction time of the fluorine-based gas to be introduced, or the reaction output. For example, the fluorine concentration in the thickness direction of the fluorine-modified portion 12a can be increased by increasing the amount of the fluorine-based gas to be introduced.

In the present invention, it is preferable to increase the fluorine concentration in the thickness direction of the fluorine-modified portion 12a from the viewpoint of imparting abrasion resistance, corrosion resistance, and stain and odor adhesion prevention properties to the inner surface of the inner container 3.

On the other hand, the fluorine-containing DLC layer 13 can be formed on the DLC layer 12 by introducing the fluorine-based gas above together with the raw material gas of the DLC layer 12 into the inner container 3 and turning it into plasma. When the concentration of the fluorine-based gas to be introduced is constant, the fluorine-containing DLC layer 13 having a high and constant fluorine concentration in the thickness direction can be formed. This makes it possible to form the inner surface of the inner container 3 having excellent wear resistance, corrosion resistance, and stain and odor adhesion prevention.

As described above, when forming the fluorine-containing DLC layer 13, it is preferable to satisfy the relationship of the formula (2) above. This makes it possible to form a good fluorine-containing DLC layer 13 on the DLC layer 12 while stably maintaining the adhesion between the inner surface of the inner container 3 and the DLC layer 12 by the insulating layer 11.

Next, in step S6 shown in FIG. 5, nitrogen (N₂) gas is introduced into the film-forming chamber so that the internal pressure of the film-forming chamber becomes normal pressure. As a result, the film-forming chamber can be opened and the heat insulating container 1 can be taken out.

By going through the steps above, it is possible to produce the heat insulating container 1 having the DLC coating on the inner surface of the inner container 3.

Further, in the method for producing the heat insulating container 1 of the present embodiment, as step S7, the intermediate layer 14 may be formed by introducing the raw material gas of the intermediate layer 14 through the introduction pipe and turning it into plasma between step S2 and step S3 or between step S3 and step S4 shown in FIG. 5.

Specifically, examples of the raw material gas of the intermediate layer 14 include organosilicon compound gases such as tetramethylsilane (Si(CH₃)₄), trimethoxysilane (SiH(OCH₃)₃) tetraethoxysilane (Si(OC₂H₅)₄), hexamethyldisilazane (C₆H₁₉NSi₂), hexamethyldisiloxane (C₆H₁₈OSi₂), and trisdimethylaminosilane (SiH[N(CH₃)₂]₃).

The raw material gas of the intermediate layer 14 is introduced into the inner container 3. At this time, the raw material gas of the intermediate layer 14 is put into a plasma state, and the intermediate layer 14 is formed while depositing the generated radicals and ions on the inner surface (base material surface) of the inner container 3 or the insulating layer 11.

Further, as described above, it is preferable to satisfy the relationships of the formulae (3) and (4) above. Thereby, the adhesiveness between the inner surface of the inner container 3 and the insulating layer 11 or between the insulating layer 11 and the DLC layer 12 can be stably maintained by the intermediate layer 14. Further, in that state, it is possible to provide the fluorine-containing DLC layer 13 having excellent properties on the DLC layer 12.

As described above, according to the method for producing the heat insulating container 1 of the present embodiment, it is possible to produce the heat insulating container 1 having the DLC coated to the inner surface of the inner container 3 in which the wear resistance and the corrosion resistance are superior to those of the conventional fluororesin coating, and the adhesion of stains and odors is prevented.

Further, according to the method for producing the heat insulating container 1 of the present embodiment, the insulating layer 11 having a large electric resistance and excellent durability can be provided on the inner surface of the inner container 3 or the intermediate layer 14. Thereby, the occurrence of point corrosion can be suppressed. Further, the heat insulating container 1 capable of keeping the surface of the inner container 3 stable can be produced by carrying out the coating treatment such as providing a DLC layer 12 on the layer.

The present invention is not necessarily limited to the embodiments above, and various modifications can be made without departing from the spirit of the present invention.

Specifically, in the heat insulating container 1, the DLC coating is applied to the entire inner surface of the inner container 3 in the embodiments above. A mouth and neck portion provided on the outer surface of the outer container 2 is provided with a male screw portion for attaching and detaching a lid body by screwing, and the male screw portion may be applied with the DLC coating. Further, the outer surface of the outer container 2 may be applied with the DLC coating together with the inner surface of the inner container 3.

Further, the fluorine-modified portion 12a or the fluorine-containing DLC layer 13 may be omitted, and the insulating layer 11 and the DLC layer 12 may be sequentially laminated on the inner surface of the inner container 3.

The intermediate layer 14, the insulating layer 11, and the DLC layer 12 may be sequentially laminated on the inner surface of the inner container 3.

The insulating layer 11, the intermediate layer 14, and the DLC layer 12 may be sequentially laminated on the inner surface of the inner container 3.

### EXPLANATION OF REFERENCE NUMERALS

1 heat insulating container
2 outer container
3 inner container
4 vacuum heat insulating layer
11 insulating layer
12 DLC layer
12a fluorine-modified portion
13 fluorine-containing DLC layer
14 intermediate layer

What is claimed is:

1. A heat insulating container comprising:
an outer container and an inner container which are made of metal and have one end open, and the inner container is housed inside the outer container, the open ends are joined to each other, and a vacuum insulating layer is formed between the outer container and the inner container,
wherein an insulating layer and a diamond-like carbon (DLC) layer are sequentially laminated on an inner surface of the inner container.

2. The heat insulating container according to claim 1,
wherein a thickness of the insulating layer is equal to or greater than a thickness of the DLC layer.

3. The heat insulating container according to claim 1,
wherein a total thickness of each layer laminated on the inner surface of the inner container is 4 to 250 nm.

4. The heat insulating container according to claim 2,
wherein when the thickness of the insulating layer is A and the thickness of the DLC layer is B, a relationship of the following formula is satisfied,
A:B=(1 to 9):1.

5. The heat insulating container according to claim 1,
wherein a surface of the DLC layer is modified with fluorine.

6. The heat insulating container according to claim 1,
wherein a fluorine-containing DLC layer is laminated on the DLC layer.

7. The heat insulating container according to claim 6,
wherein when a thickness of the insulating layer is A, a thickness of the DLC layer is B, and a thickness of the fluorine-containing DLC layer is C, a relationship of the following formula is satisfied,
A:B:C=(5 to 8):(1 to 2.5):(1 to 2.5).

8. The heat insulating container according to claim 1,
wherein the insulating layer is made of a silicon oxide film containing silicon and oxygen, and
the DLC layer is made of an amorphous hard carbon film containing carbon and hydrogen.

9. The heat insulating container according to claim 1,
wherein an intermediate layer, the insulating layer, and the DLC layer are sequentially laminated on the inner surface of the inner container.

10. The heat insulating container according to claim 1,
wherein the insulating layer, an intermediate layer, and the DLC layer are sequentially laminated on the inner surface of the inner container.

11. The heat insulating container according to claim 9,
wherein when a thickness of the intermediate layer is D, a thickness of the insulating layer is A, and a thickness of the DLC layer 12 is B, a relationship of the following formula is satisfied,
D:A:B=(1 to 8):(1 to 8):1.

12. The heat insulating container according to claim 9,
wherein the surface of the DLC layer is modified with fluorine.

13. The heat insulating container according to claim 9,
wherein a fluorine-containing DLC layer is laminated on the DLC layer.

14. The heat insulating container according to claim 13,
wherein when a thickness of the intermediate layer is D, a thickness of the insulating layer is A, a thickness of the DLC layer is B, and a thickness of the fluorine-containing DLC layer is C, a relationship of the following formula is satisfied,
D:A:B:C=(1 to 8):(1 to 8):(1 to 2.5):(1 to 2.5).

15. The heat insulating container according to claim 9,
wherein the intermediate layer 14 is made of an amorphous silicon carbide film containing at least one element of nitrogen, hydrogen, and oxygen together with carbon and silicon.

16. The heat insulating container according to claim 1,
wherein an inside of the inner container is colored.

17. A method for producing a heat insulating container comprising an outer container and an inner container which are made of metal and have one end open, and the inner container is housed inside the outer container, the open ends are joined to each other, and a vacuum insulating layer is formed between the outer container and the inner container,
wherein the method comprises a step of sequentially laminating an insulating layer and a diamond-like carbon (DLC) layer on an inner surface of the inner container by using a plasma chemical vapor deposition (plasma CVD).

18. The method for producing a heat insulating container according to claim 17,
wherein a thickness of the insulating layer is equal to or greater than a thickness of the DLC layer.

19. The method for producing a heat insulating container according to claim 17,
wherein the insulating layer and the DLC layer are sequentially laminated by putting the heat insulating container in a film-forming chamber, decompressing an inside of the film-forming chamber, turning raw material gases of the insulating layer and the DLC layer sequentially introduced inside the inner container into plasma while applying a voltage between the heat insulating container on a cathode side and an auxiliary electrode on an anode side.

20. The method for producing a heat insulating container according to claim 17,
wherein the method further comprises a step of modifying a surface of the DLC layer with fluorine.

21. The method for producing a heat insulating container according to claim 17,
wherein the method further comprises a step of laminating a fluorine-containing DLC layer on the DLC layer.

22. The method for producing a heat insulating container according to claim 17,
wherein an organosilicon compound gas and a gas containing oxygen are used as a raw material gas of the insulating layer, and
a hydrocarbon-based gas is used as a raw material gas of the DLC layer.

23. The method for producing a heat insulating container according to claim 17,
wherein the method comprises a step of sequentially laminating an intermediate layer, the insulating layer, and the DLC layer on the inner surface of the inner container by using a plasma chemical vapor deposition (plasma CVD) method.

24. The method for producing a heat insulating container according to claim 17,
wherein the method comprises a step of sequentially laminating the insulating layer, an intermediate layer, and the DLC layer on the inner surface of the inner container by using a plasma chemical vapor deposition (plasma CVD) method.

25. The method for producing a heat insulating container according to claim 23,
wherein an organosilicon compound gas is used as a raw material gas of the intermediate layer.
